(19) United States
(12) Patent Application Publication
(10) Pub. No.: US 2026/0269141 A1
(43) Pub. Date: Sep. 10, 2026

(54) LOW-NOISE TUNABLE CAPACITOR AND METHOD THEREOF

(71) Applicant: Realtek Semiconductor Corp., Hsinchu (TW)

(72) Inventor: Chia-Liang (Leon) Lin, Fremont, CA (US)

(21) Appl. No.: 19/069,279

(22) Filed: Mar. 4, 2025

(51) Int. Cl. H01G 7/06

(52) U.S. Cl. CPC H01G 7/06

(57) ABSTRACT

A method of capacitance tuning operates by disposing an AC (alternating current) coupling capacitor between a first node and a second node; disposing a varactor between the second node and a third node; disposing a diode-based DC (direct current) coupling network comprising a series connection of a resistor and a diode between the second node and a fourth node, wherein an impedance of the resistor is substantially greater than an impedance of the varactor at a frequency of interest; applying a control voltage that is subject to dynamic variation to the third node; and applying a bias voltage that is substantially static to the fourth node.

### BACKGROUND OF THE DISCLOSURE

### Field of the Disclosure

The present disclosure generally relates to tunable capacitor and more particularly to tunable capacitor that can reduce noise contribution.

### Description of Related Art

Persons having ordinary skill in the art are familiar with terms and basic concepts related to microelectronics as used in this disclosure, such as “voltage,” “current,” “signal,” “noise,” “bias,” “AC (alternating current),” “DC (direct current)” “resistor,” “capacitor,” “capacitance,” “resistance,” “diode,” “impedance,” “CMOS (complementary metal-oxide semiconductor),” “NMOS (n-channel metal-oxide semiconductor) transistor,” and “PMOS (p-channel metal-oxide semiconductor) transistor.” These terms are used within the context of microelectronics, and the associated concepts are apparent to those skilled in the art, thereby obviating the need for a detailed explanation herein.

A MOS transistor, whether PMOS or NMOS, is said to be configured in a diode-connected topology when its gate is electrically connected to its drain terminal.

In the present disclosure, a signal is defined as a voltage of a variable level that carries specific information and may vary over time. The level of the signal at any given moment indicates its state at that moment.

A capacitor is a two-terminal device that allows a current to flow in and establish a voltage that is an integral of the current. The capacitance of the capacitor quantifies a rate of the change of the voltage in response to the current.

A tunable capacitor is a capacitor of a capacitance that can be controlled by a control signal.

A “varactor” is a two-terminal device that exhibits a capacitance that is variable and determined by a voltage across its two terminals. Due to the variable capacitance nature, a varactor is widely used to embody a tunable capacitor.

As illustrated in FIG. 1, a prior art tunable capacitor 100 comprises a capacitor 111 having a fixed capacitance, which is positioned between a first node 101 and a second node 102, a varactor 121 having a variable capacitance, which is positioned between the second node 102 and a third node 103, and a resistor 131 disposed between the second node 102 and a fourth node 104. The third node 103 and the fourth node 104 are both low-impedance nodes, at which a control voltage VCTL and a bias voltage VBIAS are respectively applied. The tunable capacitor 100 is well understood by those skilled in the art, and therefore, further detailed explanation is omitted herein for brevity.

The resistor 131, employed to establish the DC condition of the varactor 121, thus determining its capacitance, serves as a significant contributor to noise.

Accordingly, what is desired is a tunable capacitor design that mitigates the noise contribution from the DC coupling resistor.

### BRIEF DESCRIPTION OF THIS DISCLOSURE

An objective of the present invention is to utilize a diode-based DC coupling network to control the capacitance of a varactor, thereby achieving a tunable capacitance while reducing the noise contribution associated with DC coupling, attributed to the intrinsic properties of the diode.

In one embodiment, a tunable capacitor comprises an AC coupling capacitor configured to provide AC coupling between a first node and a second node; a varactor disposed between the second node and a third node; and a diode-based DC coupling network configured to provide DC coupling between the second node and a fourth node, wherein a control voltage and a bias voltage are applied to the third node and the fourth node, respectively, and a DC level of the second node is approximately equal to the bias voltage offset by a threshold voltage determined by a diode embedded in the diode-based DC coupling network.

In one embodiment, a method of capacitance tuning in accordance with an embodiment of the present disclosure comprises: disposing an AC (alternating current) coupling capacitor between a first node and a second node; disposing a varactor between the second node and a third node; disposing a diode-based DC (direct current) coupling network comprising a series connection of a resistor and a diode between the second node and a fourth node, wherein an impedance of the resistor is substantially greater than an impedance of the varactor at a frequency of interest; applying a control voltage that is subject to dynamic variation to the third node; and applying a bias voltage that is substantially static to the fourth node.

### BRIEF DESCRIPTION OF THE DRAWINGS

FIG. 1 shows a schematic diagram of a prior art tunable capacitor.

FIG. 2 shows a schematic diagram of a tunable capacitor in accordance with an embodiment of the present disclosure.

FIG. 3 shows a flow diagram of a method of capacitance tuning in accordance with an embodiment of the present disclosure.

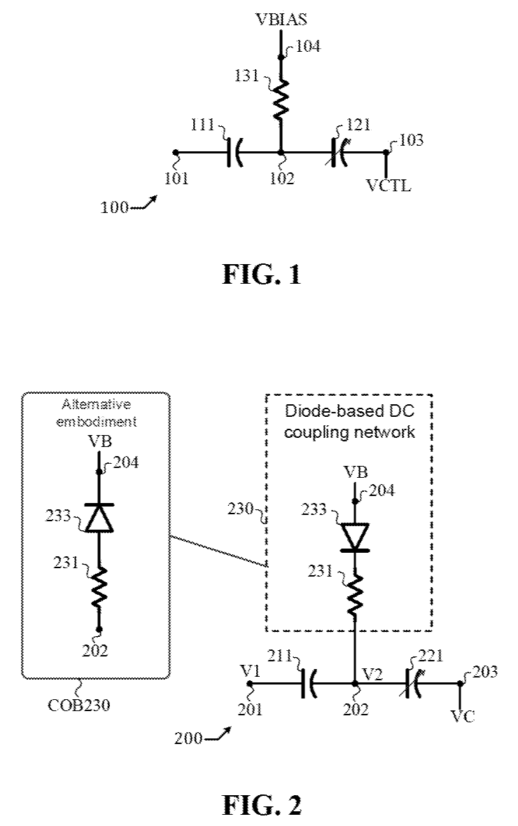

### DETAILED DESCRIPTION OF THIS DISCLOSURE

The present disclosure is directed to tunable capacitor. While the specification describes several example embodiments of the disclosure considered favorable modes of practicing the invention, it should be understood that the invention can be implemented in many ways and is not limited to the particular examples described below or to the particular manner in which any features of such examples are implemented. In other instances, well-known details are not shown or described to avoid obscuring aspects of the disclosure.

The present disclosure is described from an engineering standpoint. For example, with reference to two variables, X and Y, when it is stated that “X is equal to Y,” it signifies that “X is approximately equal to Y,” denoting that “a difference between X and Y is within a specified engineering tolerance.” Similarly, when it is asserted that “X is zero,” it implies that “X is approximately zero,” meaning that “X is within a specified engineering tolerance.” The expression “X is substantially smaller than Y” denotes that “X is negligible with respect to Y,” indicating that “the ratio between X and Y is within a specified engineering tolerance, thereby rendering X negligible in comparison to Y.”

As illustrated in FIG. 2, a tunable capacitor 200 in accordance with the present disclosure comprises: an AC (alternating current) coupling capacitor 211 configured to provide AC coupling between a first node 201 and a second node 202; a varactor 221 disposed between the second node 202 and a third node 203; and a diode-based DC (direct current) coupling network 230 configured to provide DC coupling between the second node 202 and a fourth node 204. Both the third node 203 and the fourth node 204 are low-impedance nodes, at which a control voltage VC and a bias voltage VB are applied, respectively. The DC level of the second node 202 is approximately equal to the bias voltage VB offset by a threshold voltage determined by a diode 233 embedded in the diode-based DC coupling network 230. It is noted that a “low-impedance” node signifies its impedance is smaller than the impedance of the circuit element it connects to. Specifically, in the tunable capacitor 200, the third node 203 can be regarded as a low-impedance node if its impedance is smaller than the impedance of the varactor 221, and the fourth node 204 can be regarded as a low-impedance node if its impedance is smaller than the impedance of the diode-based DC coupling network 230.

The diode-based DC coupling network 230 comprises a series connection of a resistor 231 and the diode 233 disposed between the second node 202 and the fourth node 204. At the application frequency of interest of the tunable capacitor 200, the impedance of the resistor 231 is substantially larger than the impedance of the varactor 221; thus, the diode-based DC coupling network 230 can be considered negligible, rendering the tunable capacitor 200 equivalent to a series connection of the AC coupling capacitor 211 and the varactor 221. The capacitance of the varactor 221 is determined by a voltage difference between the second node 202 and the third node 203. The bias voltage VB is substantially static, while the control voltage VC is subject to dynamic variation. Consequently, the capacitance of the varactor 221 is subject to dynamic variation in response to a change in the control voltage VC.

The DC level of a second voltage V2 at the second node 202 is approximately equal to the bias voltage VB minus a threshold voltage of the diode 233. When the tunable capacitor 200 is employed in an application circuit, a first voltage V1 is applied to the first node 201, wherein V1 embodies an AC signal that is oscillatory. By virtue of the coupling of the AC coupling capacitor 211, V2 is oscillatory around the level of the bias voltage VB minus the threshold voltage of the diode 233. The diode 233 is rendered non-conductive during the upper half cycle of the oscillation when V2 exceeds the level of the bias voltage VB minus the threshold voltage of the diode 233. Consequently, the noise contribution of the DC coupling resistors 231 is reduced by half compared to the case in the prior art tunable capacitor 100. Therefore, the tunable capacitor 200 exhibits superior performance due to the reduced noise.

In an alternative embodiment illustrated in callout box COB230, the diode 233 is disposed in reverse polarity. In this alternative embodiment, the DC level of the second voltage V2 is approximately equal to the bias voltage VB plus a threshold voltage of the diode 233, and the diode 233 is rendered non-conductive during the lower half cycle of the oscillation when the second voltage V2 is below the bias voltage VB plus the threshold voltage of the diode 233. Thus, the advantage of noise reduction is maintained.

In one embodiment, the tunable capacitor 200 is fabricated using CMOS (complementary metal-oxide semiconductor) technology, wherein a diode may be implemented by configuring either a PMOS transistor or an NMOS transistor in a diode-connected topology, where the drain terminal and the gate terminal are electrically tied together. The "diode-connected" topology is well understood by those skilled in the art and thus does not require further explanation herein.

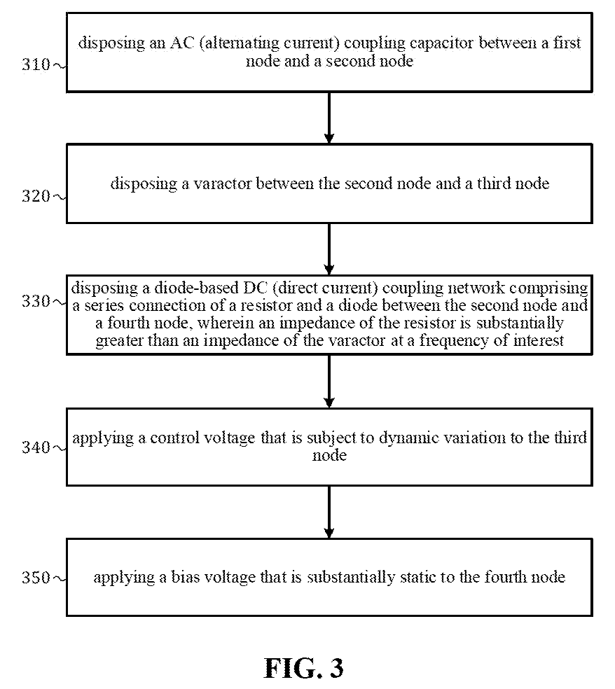

As illustrated in FIG. 3, a method of capacitance tuning is disclosed. The method comprises: (step 310) disposing an AC (alternating current) coupling capacitor between a first node and a second node; (step 320) disposing a varactor between the second node and a third node; (step 330) disposing a diode-based DC (direct current) coupling network comprising a series connection of a resistor and a diode between the second node and a fourth node, wherein an impedance of the resistor is substantially greater than an impedance of the varactor at a frequency of interest; (step 340) applying a control voltage that is subject to dynamic variation to the third node; and (step 350) applying a bias voltage that is substantially static to the fourth node.

Those skilled in the art will readily observe that numerous modifications and alterations of the device and method may be made while retaining the teachings of the disclosure. Accordingly, the above disclosure should not be construed as limited only by the metes and bounds of the appended claims.

What is claimed is:

1. A tunable capacitor comprising:
an AC (alternating current) coupling capacitor configured to provide AC coupling between a first node and a second node;
a varactor disposed between the second node and a third node; and
a diode-based DC (direct current) coupling network configured to provide DC coupling between the second node and a fourth node, wherein a control voltage and a bias voltage are applied to the third node and the fourth node, respectively, and a DC level of the second node is approximately equal to the bias voltage offset by a threshold voltage determined by a diode embedded in the diode-based DC coupling network.

2. The tunable capacitor of claim 1, wherein the diode-based DC coupling network comprises a series connection of a resistor and the diode.

3. The tunable capacitor of claim 2, wherein an impedance of the resistor is substantially larger than an impedance of the varactor.

4. The tunable capacitor of claim 3, wherein the impedance of the resistor is at least three times larger than the varactor.

5. The tunable capacitor of claim 4, wherein the diode is a MOS (metal-oxide semiconductor) transistor configured in a “diode-connected” topology wherein its gate is electrically shorted to its drain.

6. The tunable capacitor of claim 1, wherein the bias voltage is substantially static.

7. The tunable capacitor of claim 6, wherein the control voltage is subject to dynamic variation.

8. A method of capacitance tuning comprising:
disposing an AC (alternating current) coupling capacitor between a first node and a second node;
disposing a varactor between the second node and a third node;
disposing a diode-based DC (direct current) coupling network comprising a series connection of a resistor and a diode between the second node and a fourth node, wherein an impedance of the resistor is substantially greater than an impedance of the varactor at a frequency of interest;
applying a control voltage that is subject to dynamic variation to the third node; and
applying a bias voltage that is substantially static to the fourth node.

9. The method of capacitance tuning of claim 8, wherein the impedance of the resistor is substantially larger than the impedance of the varactor.

10. The method of capacitance tuning of claim 9, wherein the impedance of the resistor is at least three-times larger than the impedance of the varactor.
